(19) United States
(12) Patent Application Publication
(10) Pub. No.: US 2016/0284957 A1
(43) Pub. Date: Sep. 29, 2016

(54) REFLECTIVE CONTACT FOR GaN-BASED LEDS

(71) Applicant: Toshiba Corporation, Tokyo (JP)

(72) Inventor: Taisuke Sato, Pleasanton, CA (US)

(21) Appl. No.: 14/665,632

(22) Filed: Mar. 23, 2015

(51) Int. Cl. H01L 33/62; H01L 33/32; H01L 33/00; H01L 33/10

(52) U.S. Cl. CPC H01L 33/62; H01L 33/10; H01L 33/32; H01L 33/0095; H01L 33/0075; H01L 2933/0066

(57) ABSTRACT

A method for forming a light emitting diode (LED) assembly with a reflective contact and an LED assembly formed by the method is disclosed. In one embodiment, the method includes forming an LED on a surface of a substrate, the LED comprising a light emitting layer disposed between a first layer comprising a compound semiconductive material having a first conductivity type, and a second layer comprising the compound semiconductive material having a second conductivity type, the compound semiconductive material comprising a group III element and a group V element. The method further includes forming an oxidized region extending inwards of a surface of the first layer opposite the second layer. In one embodiment, the oxidized region is formed by oxygen (O₂) plasma ashing the surface of the first layer.

### FIELD OF THE INVENTION

This invention generally relates to semiconductor light emitting diode (LED) devices and assemblies.

### BACKGROUND OF THE INVENTION

In general, light emitting diodes (LEDs) begin with a semiconductor growth substrate, typically a group III-V compound. Epitaxial semiconductor layers are grown on the semiconductor growth substrate to form the N-type and P-type semiconductor layers of the LED. A light emitting layer is formed at the interface between the N-type and P-type semiconductor layers of the LED. After the epitaxial semiconductor layers are formed, electrical contacts are coupled to the N-type and P-type semiconductor layers. Individual LEDs are diced and mounted to a package with wire bonding. An encapsulant is deposited onto the LED, and the LED is sealed with a protective lens which also aids in light extraction. When a voltage is applied to the electrical contacts, a current will flow between the contacts, causing photons to be emitted by the light emitting layer.

There are a number of different types of LED assemblies, including lateral LEDs, vertical LEDs, flip-chip LEDs, and hybrid LEDs (a combination of the vertical and flip-chip LED structure). Most types of LED assemblies utilize a reflective contact between the LED and the underlying substrate or submount to reflect photons which are generated downwards toward the substrate or submount. By using a reflective contact, more photons are allowed to escape the LED rather than be absorbed by the substrate or submount, improving the overall light output power and light output efficiency of the LED assembly. The higher the reflectivity of the contact, the greater the improvement in the light output power and light output efficiency.

Typically, silver (Ag) is used for the reflective contact due to its high degree of reflectivity (greater than 90% in the visible wavelength range). However, silver (Ag) suffers from agglomeration during the annealing process required to form an ohmic contact with the LED, particularly gallium nitride (GaN) based LEDs. Agglomeration of the silver (Ag) contact severely degrades the optical reflectivity of the contact. For example, Song et al., Ohmic and Degredation Mechanisms of Ag Contacts on P-type GaN, Applied Physics Letters 86, 062104 (2005), which is incorporated herein by reference, discloses that the optical reflectivity of the silver (Ag) contact prior to annealing was 92.2% at 460 nm wavelength, but decreased to 84.2% after annealing at 330° C., and 72.8% after annealing at 530° C. The temperatures discussed above are within the typical range necessary to create an ohmic contact between the silver (Ag) contact and the semiconductor material of the LED.

The effect of the agglomeration of silver (Ag) contact can be seen in FIGS. 1 and 2. FIG. 1 shows a Transmission Electron Microscopy (TEM) image of the cross-sectional view of a conventional vertical LED assembly with a pure silver (Ag) contact after annealing. FIG. 2 shows a Scanning Electron Microscope (SEM) image of the surface of a pure silver (Ag) contact after annealing. As illustrated in FIG. 1, an LED comprises a light emitting layer 106 formed between a P-type gallium nitride (p-GaN) layer 104 and an N-type gallium nitride (n-GaN) layer 108. A pure silver (Ag) contact 110 is deposited below the P-type gallium nitride (p-GaN) layer 104. After annealing, the pure silver (Ag) contact 110 agglomerates, resulting in an uneven layer with some regions nearly twice as thick as others. The agglomeration of the pure silver (Ag) contact 110 propagates to underlying metal bonding layer 113. In FIG. 2, the surface of agglomerated silver (Ag) is extremely uneven, dotted with silver (Ag) islands (higher concentration of silver (Ag) material) resulting in a thicker layer of silver (Ag) in some regions, while other regions have a substantially thinner layer of silver (Ag).

To prevent the agglomeration of silver (Ag), one conventional approach is to deposit a thin layer of nickel (Ni) between the LED and the silver (Ag) contact. This approach is detailed, for example, in Son et al., Effects of Ni Cladding Layers on Suppression of Ag Agglomeration in Ag-based Ohmic Contacts on p-GaN, Applied Physics Letters 95, 062108 (2009), and in Jang et al., Mechanism for Ohmic Contact Formation of Ni/Ag Contacts on P-type GaN, Applied Physics Letters 85, 5920 (2004), both of which are incorporated herein by reference. However, it is also generally understood that nickel (Ni) has a lower optical reflectivity than silver (Ag), and therefore, the use of a nickel/silver (Ni/Ag) contact will have correspondingly lower light output power and light output efficiency. To illustrate this point, as disclosed by Son et al., the use of a nickel/silver/nickel (Ni/Ag/Ni) layered contact was only able to achieve a light reflectance of 84.1% after annealing at 500° C., an improvement over an agglomerated pure silver (Ag) contact, but still far short of the greater than 90% reflectivity of pure silver (Ag), as discussed above.

A conventional vertical gallium nitride (GaN) based LED assembly utilizing a nickel/silver (Ni/Ag) contact according to the prior art is shown in FIGS. 3A-3C. FIG. 3A is a cross-sectional view of vertical LED assembly 300, and FIG. 3B is an expanded cross-sectional view of the vertical LED assembly 300, corresponding to area AA shown in FIG. 3A. FIG. 3C is a Transmission Electron Microscopy (TEM) image of the expanded cross-sectional view of the vertical LED assembly 300 corresponding to FIG. 3A. As shown in FIGS. 3A-3C, a light emitting layer 306 is formed between a P-type gallium nitride (p-GaN) layer 304 and an N-type gallium nitride (n-GaN) layer 308. The P-type gallium nitride (p-GaN) layer 304, the light emitting layer 306, and the N-type gallium nitride (n-GaN) layer 308 comprise LED 301.

A layer of nickel (Ni) 314 is disposed between the P-type gallium nitride (p-GaN) layer 304 and a layer of silver (Ag) 310. Together, the layer of nickel (Ni) 314 and the layer of silver (Ag) 310 comprise an electrical contact that is electrically coupled to the P-type gallium nitride (p-GaN) layer 304 after annealing. The LED 301 is bonded to the substrate 302 by bonding layer 313. A second contact 312 is electrically coupled to the N-type gallium nitride (n-GaN) layer 308. During device operation, when a voltage is applied to the contacts 312 and 310 and 314, the light emitting layer emits photons 311. Photons 311 which are emitted downwards towards substrate 302 are reflected back by the nickel (Ni) layer 314 and silver (Ag) layer 310.

The layer of nickel (Ni) 314 effectively acts as an anchor for the layer of silver (Ag) 310, such that during annealing, agglomeration of the silver (Ag) layer 310 is reduced, and silver (Ag) layer 310 retains a substantially uniform thickness throughout the layer, as illustrated in FIG. 3C. However, as disclosed by Son et al., the layer of nickel (Ni) 314 reduces the overall reflectivity of the contact, which in turn reduces the overall light output power and light output efficiency. FIG. 4 shows a plot of the as-deposited reflectivity of a contact comprising silver (Ag) compared to the thickness of the layer of nickel (Ni) used to avoid agglomeration of the silver (Ag). One atomic layer of nickel (Ni) is approximately 0.29 nm in thickness. As shown in FIG. 4, only one atomic layer of nickel (Ni), having a thickness of 0.29 nm, reduces the reflectivity by about 1.5%. As the layer of nickel (Ni) increases, the reflectivity correspondingly decreases. At a thickness of nickel (Ni) greater than 1 nm, the reflectivity of the contact falls below 90%.

FIG. 5 is a Secondary Ion Mass Spectrometry (SIMS) plot of the vertical LED assembly of FIG. 3A. Line 502 corresponds to silver (Ag), line 504 corresponds to gallium (Ga), line 506 corresponds to magnesium (Mg), line 508 corresponds to nitride (N), line 510 corresponds to nickel (Ni), and line 512 corresponds to oxygen (O). As shown in FIG. 5, lines 502 (silver (Ag)), 504 (gallium (Ga)), 508 (nitride (N)), 510 (nickel (Ni)), and 512 (oxygen (O)) correspond with the left y-axis labeled “Secondary ion intensity,” and line 506 (magnesium (Mg)) corresponds to the right y-axis labeled “Concentration.” As shown in FIG. 5, the layer of nickel (Ni) 314 (represented by line 502) is approximately peaks at the interface of the gallium nitride (GaN) layer (where gallium (Ga), line 506, and nitride (N), line 508, rise in concentration starting at around a depth of 0.12 μm), corresponding to a nickel layer of about 1 nm between the silver (Ag) contact, line 502, and the gallium nitride (GaN) layer. Referring back to the plot of FIG. 4, a 1 nm layer of nickel (Ni) easily reduces the reflectivity of the contact below 90%.

Another conventional approach to prevent the agglomeration of silver (Ag) is to deposit a layer of titanium oxide (TiO₂) around the silver (Ag) contact prior to annealing so that the titanium oxide (TiO₂) essentially forms a seal around the silver (Ag), preventing agglomeration of the silver (Ag). This approach is disclosed, for example, in Kondoh et al., U.S. Pat. Nos. 6,194,743 and 7,262,436, both of which are incorporated herein by reference. However, as Kondoh et al. discloses, the titanium oxide (TiO₂) reduces the reflectance of the silver (Ag) which it surrounds. Moreover, depositing an additional titanium oxide (TiO₂) layer requires additional mask patterning, deposition, and etching steps, increasing the overall manufacturing cost of the LED assembly of Kondoh et al.

There is, therefore, an unmet demand for LED assemblies with an improved reflective contact having a reflectance greater than 90% in the visible wavelength range that does not agglomerate after annealing.

### BRIEF DESCRIPTION OF THE INVENTION

In one embodiment, a light emitting diode (LED) assembly includes an LED comprising a light emitting layer disposed between a first layer having a first conductivity type and a second layer having a second conductivity type. The first and second layers comprise gallium nitride (GaN). The first layer is initially of a P-type doping, and the second layer is initially of an N-type doping. In one embodiment, the first layer is doped with magnesium (Mg). In one embodiment, the second layer is doped with silicon (Si). The first layer has an oxidized region comprising gallium oxide (Ga₂O₃) extending inwards of a surface of the first layer opposite the second layer. In one embodiment, the oxidized region has a ratio of a concentration of oxygen compared to a concentration of gallium (Ga) of 1:1000 to 1:10. In one embodiment, the oxidized region extends up to 70 nm inwards of the surface of the first layer. The LED assembly further includes a first contact disposed on the surface of the first layer opposite the second layer, and electrically coupled to the first layer. The first contact forms an ohmic contact with the first layer. In one embodiment, the first contact comprises a single element or alloy, such as silver (Ag). In one embodiment, the first contact is substantially free of nickel (Ni) at the interface of the first contact and the first layer. The first contact has a uniform thickness, and a planar surface opposite the first layer substantially free of projections and indentations. The first contact has an optical reflectivity between 90% and 99% in the visible wavelength range. In one embodiment, the first contact has an optical reflectivity greater than 94%, and up to 99%.

The LED assembly further includes a second contact disposed on the second layer, and electrically coupled to the second layer. When a voltage is applied to the first and second contacts, the light emitting layer emits photons. The photons which are initially emitted towards the first contact will be reflected by the first contact and given another opportunity to escape the LED as visible light, thereby increasing the light output power and light output efficiency of the LED. In one embodiment, the LED assembly is a vertical LED assembly. In another embodiment, the LED assembly is a flip-chip LED assembly. In yet another embodiment, the LED assembly is a hybrid LED assembly.

In one embodiment, a method of forming a light emitting diode (LED) assembly includes forming an LED on a substrate, the LED comprising a light emitting layer disposed between a first layer having a first conductivity type and a second layer having a second conductivity type. The first and second layers comprise gallium nitride (GaN). The first layer is initially of a P-type doping, and the second layer is initially of an N-type doping. In one embodiment, the first layer is initially doped with magnesium (Mg). In one embodiment, the second layer is initially doped with silicon (Si). The method further includes forming an oxidized region extending inwards of a surface of the first layer opposite the second layer. In one embodiment, the oxidized region is formed by oxygen (O₂) plasma ashing the surface of the first layer. In one embodiment, the LED is baked prior to forming the oxidized region. In one embodiment, the LED is baked in an environment comprising nitrogen (N₂) and oxygen (O₂). Once formed, the oxidized region has a ratio of a concentration of oxygen compared to a concentration of gallium (Ga) of 1:1000 to 1:10. In one embodiment, the oxidized region extends up to 70 nm inwards of the surface of the first layer.

The method further includes depositing a first contact on the surface of the first layer. In one embodiment, the first contact comprises a single element or alloy, such as silver (Ag). In one embodiment, the first contact is substantially free of nickel (Ni) at the interface of the first contact and the first layer. The method further includes annealing the first contact to form an ohmic contact with the first layer. In one embodiment, the first contact is annealed at a temperature greater than 300° C. and less than 450° C. In one embodiment, the first contact is annealed in an environment comprising about 80% nitrogen (N₂) and about 20% oxygen (O₂). After annealing, the first contact has a uniform thickness, and a planar surface opposite the first layer substantially free of projections and indentations. The first contact has an optical reflectivity after the annealing step substantially similar to an optical reflectivity of the first electrode after the deposition step and before the annealing step. In one embodiment, the first contact has an optical reflectivity greater than 94%, and up to 99%.

In one embodiment, the method further includes bonding the LED to a handling substrate, and removing the substrate the LED was original formed on. A second electrode is deposited on the second layer and annealed to form an ohmic contact with the second layer. In another embodiment, the method further includes etching the first layer and the light emitting layer to expose a surface of the second layer. A second electrode is deposited on the surface of the second layer and annealed to form an ohmic contact with the second layer. A submount having a first interconnect and a second interconnect is attached to the LED, with the first interconnect electrically coupled to the first contact, and the second interconnect electrically coupled to the second contact.

### BRIEF DESCRIPTION OF THE FIGURES

FIG. 1 shows a Transmission Electron Microscopy (TEM) image of a vertical LED assembly with a pure silver (Ag) contact after annealing, according to the prior art.

FIG. 2 shows a Scanning Electron Microscope (SEM) image of the surface of a pure silver (Ag) contact after annealing, according to the prior art.

FIG. 3A shows a cross-sectional view of a vertical LED assembly of the prior art.

FIG. 3B shows an expanded cross-sectional view of the vertical LED assembly of FIG. 3A.

FIG. 3C shows a Transmission Electron Microscopy (TEM) image of the expanded cross-sectional view of the vertical LED assembly of FIG. 3A.

FIG. 4 shows a plot of the as-deposited reflectivity of a contact comprising silver (Ag) compared to the thickness of a layer of nickel (Ni) used to avoid agglomeration of the silver (Ag).

FIG. 5 shows a Secondary Ion Mass Spectrometry (SIMS) plot of the vertical LED assembly of FIG. 3A.

FIG. 6 A shows a cross-sectional view of a vertical LED assembly according to one embodiment of the invention.

FIG. 6B shows an expanded cross-sectional view of the vertical LED assembly of FIG. 6A.

FIG. 6C shows a Transmission Electron Microscopy (TEM) image of the expanded cross-sectional view of the vertical LED assembly of FIG. 6A.

FIG. 7 shows a Secondary Ion Mass Spectrometry (SIMS) plot of the vertical LED assembly of FIG. 6A according to one embodiment of the invention.

FIGS. 8A-8G show cross-sectional views of the manufacturing steps for producing a vertical LED assembly, according to one embodiment of the invention.

FIGS. 9A-9B shows cross-sectional views of the alternative manufacturing steps for producing a flip-chip LED assembly, according to another embodiment of the invention.

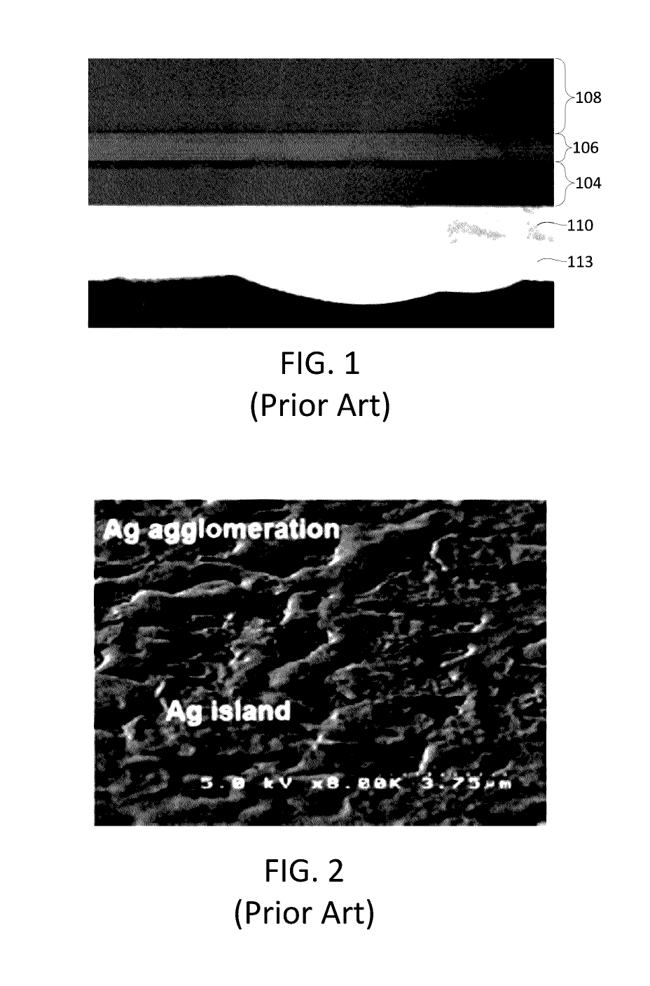

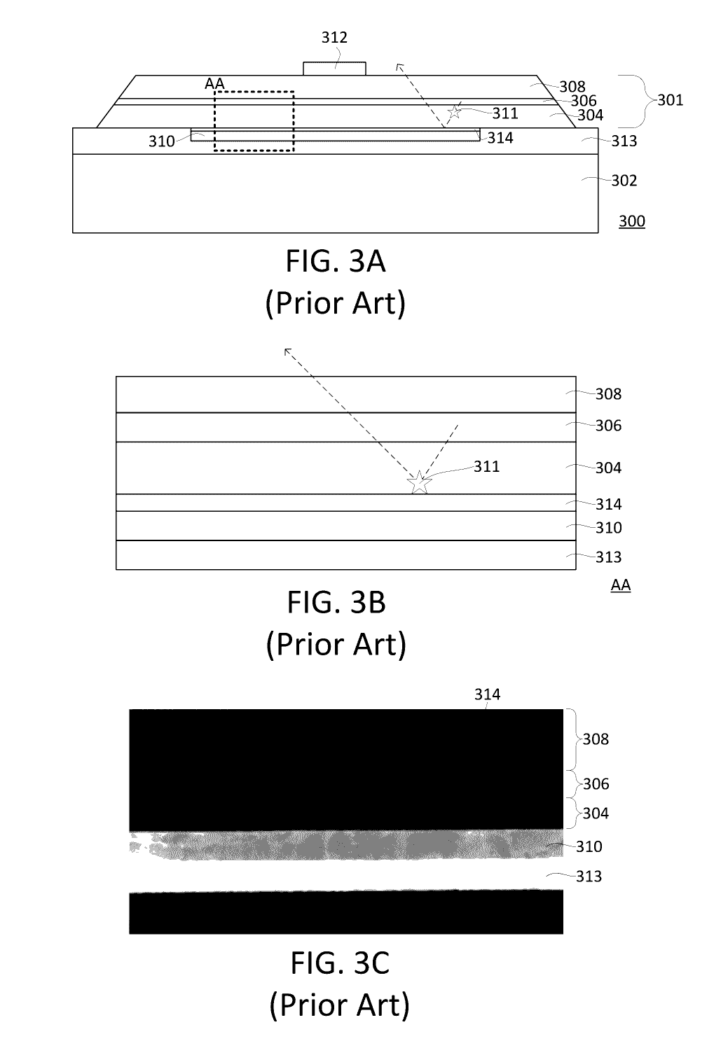

### DETAILED DESCRIPTION OF THE INVENTION

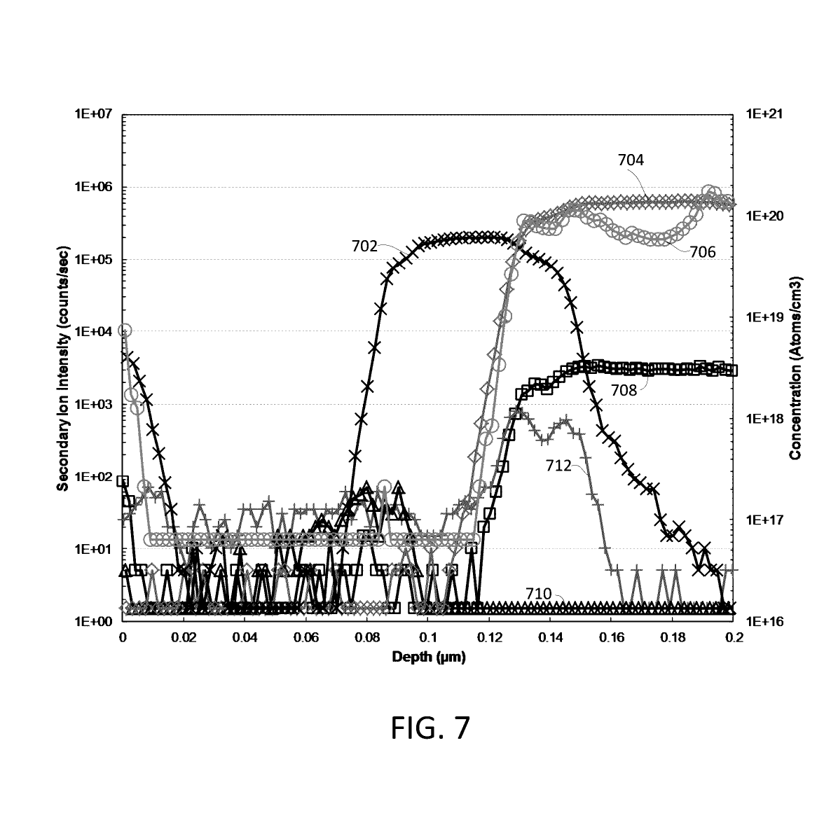

FIG. 6A shows a cross-sectional view of a vertical LED assembly 600 according to one embodiment of the invention. FIG. 6B shows an expanded cross-sectional view of the vertical LED assembly 600, corresponding to area BB shown in FIG. 6A. FIG. 6C is a Transmission Electron Microscopy (TEM) image of the expanded cross-sectional view of the vertical LED assembly 600 of FIG. 6A. As shown in FIGS. 6A-B, an LED 601 comprises a light emitting layer 606 disposed between a first semiconductor layer 604 and a second semiconductor layer 608. The first semiconductor layer 604 and the second semiconductor layer 608 comprise gallium nitride (GaN). The first semiconductor layer 604 is P-type gallium nitride (p-GaN), and the second semiconductor layer 608 is N-type gallium nitride (n-GaN). The P-type gallium nitride (p-GaN) may be formed by doping gallium nitride (GaN) with any suitable P-type dopant, such as magnesium (Mg), and the N-type gallium nitride (n-GaN) may be formed by doping gallium nitride (GaN) with any suitable N-type dopant, such as silicon (Si).

The first semiconductor layer 604 has an oxidized region 614. Oxidized region 614 extends inwards of a surface 603 of the first semiconductor layer 604 opposite the second semiconductor layer 608. In one embodiment, the oxidized region 614 extends less than 1 nm inwards of the surface 603 of the first semiconductor layer 604. In another embodiment, the oxidized region 614 extends less than 70 nm inwards of the surface 603. In yet another embodiment, the oxidized region 614 extends less than 0.1 μm inwards of the surface 603. The oxidized region 614 comprises gallium oxide (Ga₂O₃). In one embodiment, the oxidized region 614 has a ratio of a concentration of oxygen (O) to a concentration of gallium (Ga) of 1:1000 to 1:10.

A first contact 610 is disposed between LED 601 and the substrate 602, the first contact formed on the surface 603 of the first semiconductor layer 604, and electrically coupled to the first semiconductor layer 604. A bonding layer 613 bonds the LED 601 and the substrate 602. The first contact 610 forms an ohmic contact with the first semiconductor layer 604. The first contact 610 comprises a highly reflective single element or alloy, for example, silver (Ag). In one embodiment, a silver (Ag) first contact 610 directly contacts the surface 603 of the first semiconductor layer 604, without an intervening layer of nickel (Ni), zinc (Zn), palladium (Pd), titanium (Ti), or any other material that reduces the reflectivity of the silver (Ag) first contact 610. One of ordinary skill in the art would appreciate that the single element or alloy may have contaminants, such as other elements, due to the manufacturing methods employed.

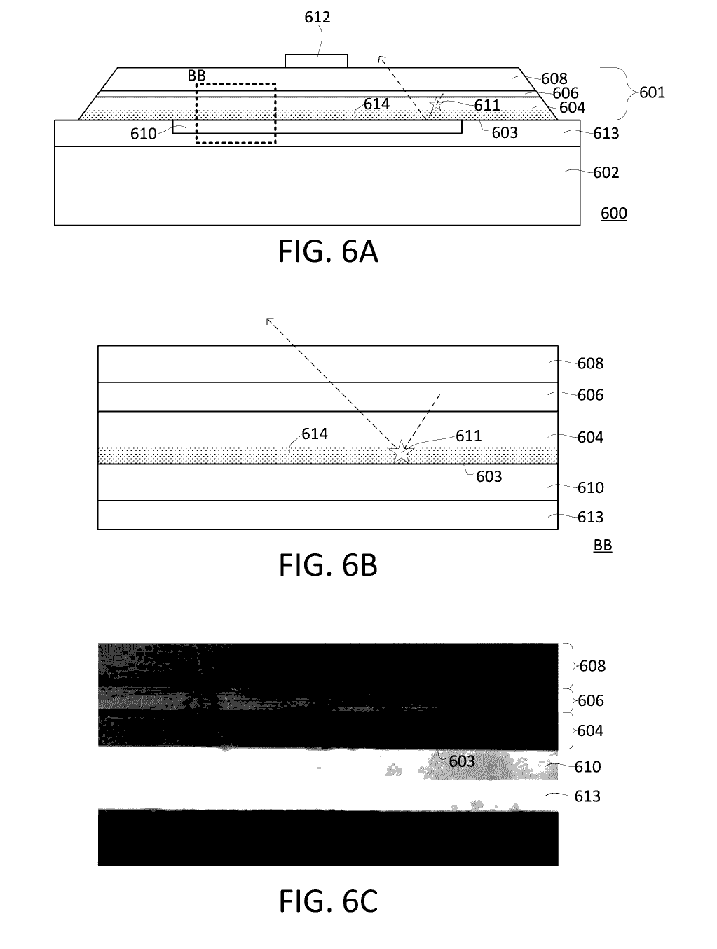

The concentration of oxygen in the oxidized region 614 of the first layer 604 suppresses agglomeration of the first contact 610, resulting in a first contact 610 having a substantially planar surface and a substantially uniform thickness, as shown in the Transmission Electron Microscopy (TEM) image in FIG. 6C. The first contact 610 is also substantially free from projections and indentations, such as the Ag islands shown in FIG. 5. As a result, the first contact 610 has an optical reflectivity between about 90% and about 99%. In one embodiment, the first contact 610 has an optical reflectivity great than 94%, and up to 99%.

A second contact 612 is formed on the second semiconductor layer 608, and is electrically coupled to the second semiconductor layer 608. During device operation, when a voltage is applied to the first contact 610 and the second contact 612, photons 611 are emitted from the light emitting layer 606. Compared to prior art devices using a layer of nickel (Ni), or any other material to prevent agglomeration of the first contact 610, such as titanium oxide (TiO₂) as disclosed in Kondoh et al., the LED assembly of FIGS. 6A-6C will have improved light output power and light output efficiency as the optical reflectivity of the first contact 610 is not degraded.

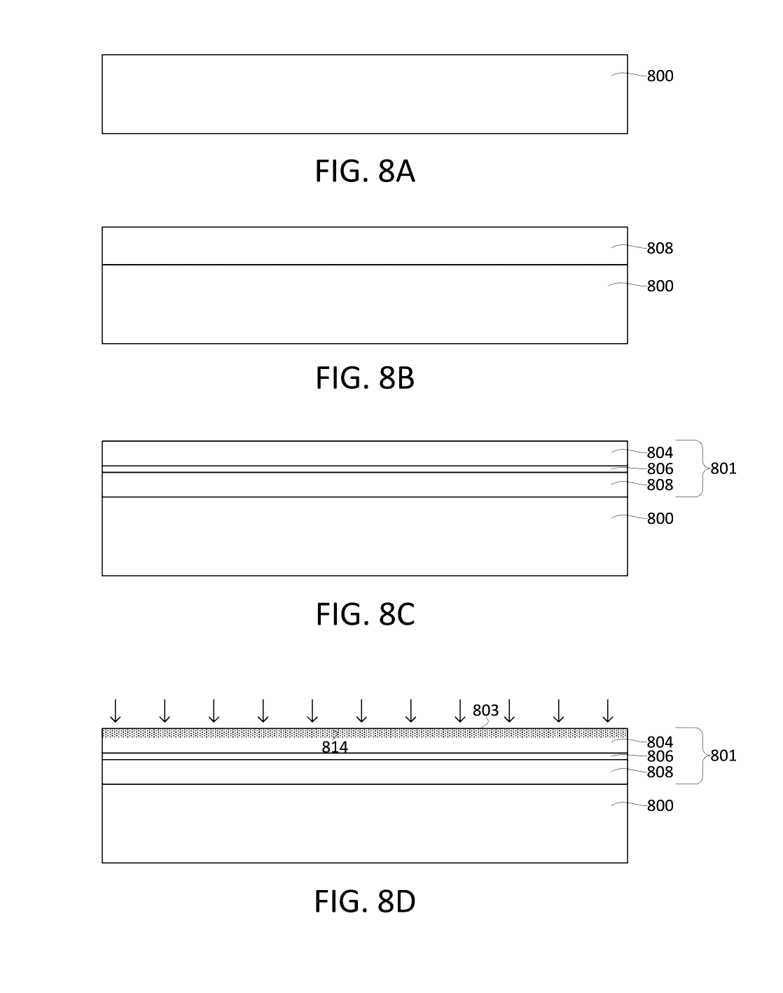

FIG. 7 shows a Secondary Ion Mass Spectrometry (SIMS) plot of the vertical LED assembly of FIG. 6A according to one embodiment of the invention. In FIG. 7, line 702 corresponds to silver (Ag), line 704 corresponds to gallium (Ga), line 706 corresponds to magnesium (Mg), line 708 corresponds to nitride (N), line 710 corresponds to nickel (Ni), and line 712 corresponds to oxygen (O). Again, as with FIG. 5, lines 702 (silver (Ag)), 704 (gallium (Ga)), 708 (nitride (N)), 710 (nickel (Ni)), and 712 (oxygen (O)) corresponds with the left y-axis labeled “Secondary ion intensity,” and line 706 (magnesium (Mg)) corresponds to the right y-axis labeled “Concentration.” As shown in FIG. 7, there is virtually no detectable amount of nickel (Ni), line 710, at the interface between silver (Ag), line 702, and gallium (Ga) and nitride (N), lines 704 and 708, respectively. There is, however, a large concentration of oxygen (O), line 712, inwards of the surface of gallium (Ga) and nitride (N), lines 704 and 708, respectively. This concentration of oxygen (O), line 712, represents an oxidized region formed inwards of the surface of a gallium nitride layer for the suppression of agglomeration of the silver (Ag).

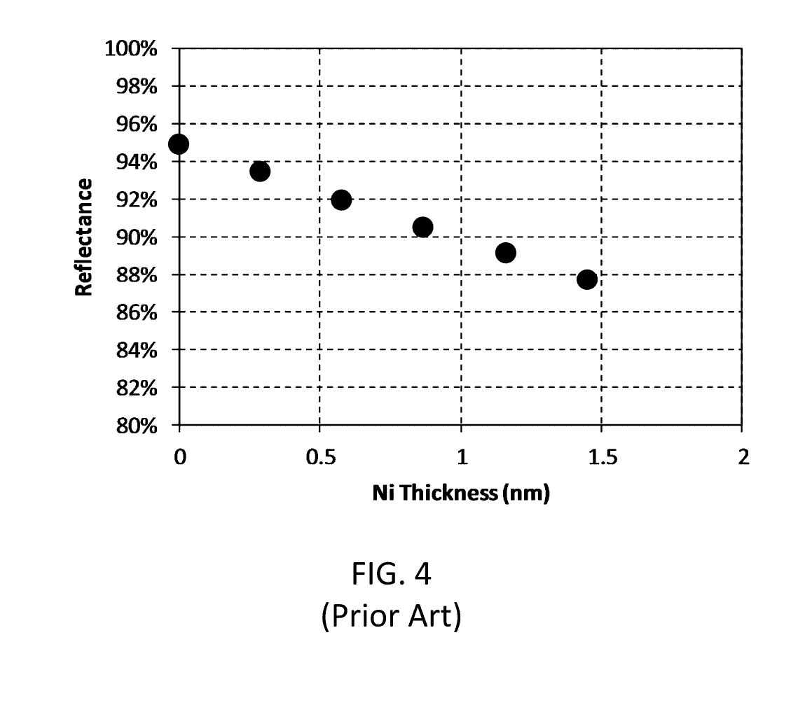

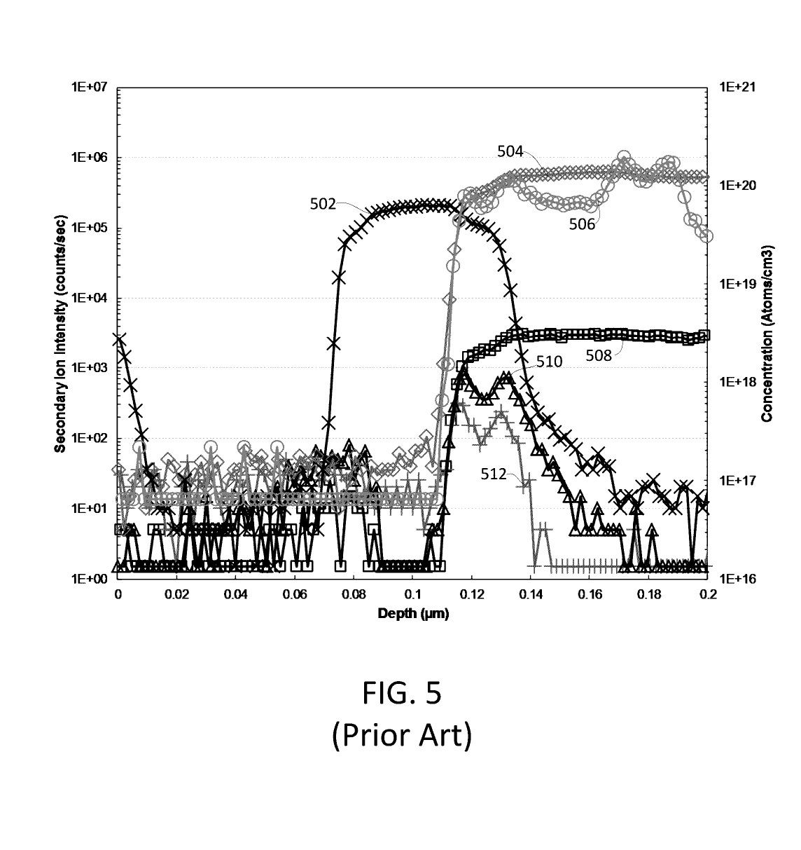

Compared with FIG. 5, the Secondary Ion Mass Spectrometry (SIMS) plot of the prior art LED assembly of FIG. 3A, the concentration of oxygen (O), line 712, at the surface of gallium (Ga) and nitride (N), lines 704 and 708, respectively, is greater by about 3.1×10² counts/sec (with oxygen (O), line 712 peaking at 8.0×10¹² counts/sec)—more than double the oxygen (O) concentration at the interface of the gallium nitride (GaN) layer shown in FIG. 5. That is because the concentration of oxygen (O) present in the prior art LED assembly of FIG. 3A is introduced as an unintentional byproduct of the manufacturing process, and not as a result of deliberate oxidization of the gallium nitride (GaN) layer in accordance with the present invention. In other experiments, it has been observed that an oxidized region having a ratio of a concentration of oxygen to a concentration of gallium (Ga) of 1:1000 to 1:10 will work to suppress agglomeration of silver (Ag).

In one experiment, the light output power an LED assembly 600 according to FIGS. 6A-6C, according to one embodiment of the present invention, was compared to the light output power of a prior art LED assembly 300 shown in FIGS. 3A-3C. Both LED assembly 600 and prior art LED assembly 300 comprised a gallium nitride (GaN) based LED, with a light emitting layer formed between a P-type gallium nitride (p-GaN) layer and an N-type gallium nitride (n-GaN) layer. Prior art LED assembly 300 utilized a first contact comprising an 100 nm layer of silver (Ag), and a very thin 0.1 nm layer of nickel (Ni), with the nickel (Ni) layer between the layer of silver (Ag) and the P-type gallium nitride (p-GaN) layer to suppress agglomeration. LED assembly 600, according to one embodiment of the invention, utilized a first contact comprising a 100 nm layer of silver (Ag), without any nickel or other material, due to the incorporation of a gallium oxide region in the P-type gallium nitride (p-GaN) to suppress agglomeration. All other parameters of the LED assembly 600 and the prior art LED assembly 300 were substantially similar. At an operating current of 350 mA, the LED assembly 600 was measured to have 4.7% greater light output power compared to the prior art LED assembly 300. This improvement over the prior art LED assembly will roughly scale linearly at higher operating conditions, assuming current crowding effects are not a limiting factor at higher currents.

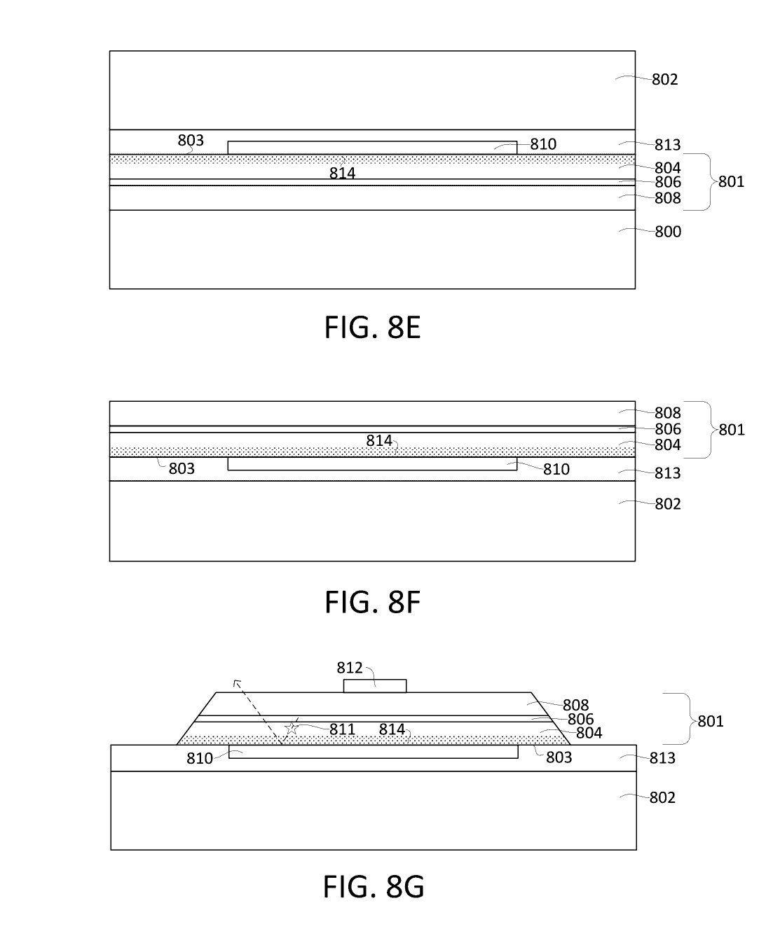

FIGS. 8A-8G show cross-sectional views of the manufacturing steps for producing a vertical LED assembly and a flip-chip LED assembly, according various embodiments of the invention. In FIG. 8A, a growth substrate 800 is provided. Growth substrate 800 is typically a wafer, and may comprise any material suitable for epitaxially growing layers of group III-V compounds. In one embodiment, growth substrate 800 comprises bulk gallium nitride (GaN). In other embodiments, growth substrate 800 may comprise sapphire (Al₂O₃), silicon (Si), or silicon carbide (SiC).

In FIG. 8B, a second semiconductor layer 808 is epitaxially grown on a surface of the growth substrate 800. The second semiconductor layer 808 comprises N-type gallium nitride (n-GaN). The N-type gallium nitride (n-GaN) may be formed by doping gallium nitride (GaN) with any suitable N-type dopant, such as silicon (Si). The second semiconductor layer 808 may be grown using any known growth method, including Metal Organic Chemical Vapor Deposition (MOCVD), Molecular Beam Epitaxy (MBE), or Liquid Phase Epitaxy (LPE). In FIG. 8C, a first semiconductor layer 804 is epitaxially grown on top of the second semiconductor layer 808. The first semiconductor layer 804 comprises P-type gallium nitride (p-GaN). The P-type gallium nitride (p-GaN) may be formed by doping gallium nitride (GaN) with any suitable P-type dopant, such as magnesium (Mg). The first semiconductor layer 804 may also be grown using any known growth method. A light emitting layer 806 is formed at the interface of the first and second semiconductor layers 804 and 808. The first semiconductor layer 804, the light emitting layer 806, and the second semiconductor layer 808 comprises an LED 801.

In FIG. 8D, an oxidized region 814 is formed inwards of a surface 803 of the first semiconductor layer 804. The oxidized region 814 comprises gallium oxide (Ga₂O₃). In one embodiment, the oxidized region 814 is formed by baking the LED 801 and oxygen (O₂) plasma ashing the surface 803 of the first semiconductor layer 804. In one embodiment, the LED 801 is baked in an environment comprising nitrogen (N₂) and oxygen (O₂). The LED 801 is baked for less than 10 minutes, and preferably baked for 5 minutes.

Oxygen (O₂) plasma ashing is generally considered to be a mild plasma treatment that will not damage the surface 803 of the first semiconductor layer 804 while forming the oxidized region 814. In one embodiment, the surface 803 of the first semiconductor layer 804 is oxygen (O₂) plasma ashed for about one minute. In another embodiment, the oxygen (O₂) plasma ashing lasts for about two minutes. After oxygen (O₂) plasma ashing, in one embodiment, the oxidized region 814 extends less than 1 nm inwards of the surface 803 of the first semiconductor layer 804. In another embodiment, the oxidized region 814 extends less than 70 nm inwards of the surface 803. After oxygen (O₂) plasma ashing, the oxidized region 814 has a ratio of a concentration of oxygen compared to a concentration of gallium (Ga) of 1:1000 to 1:10.

In FIG. 8E, a handling substrate 802 (also a wafer is bonded to the surface 803 of the first semiconductor layer 804 of the LED 801. The bonding is accomplished using any known wafer bonding process, such as eutectic bonding where a bonding layer 813 is heated and pressure is applied to bond the handling substrate 802 to the LED 801. A first contact 810 is deposited on the surface 803 of the first semiconductor layer 804. The first contact 810 comprises a highly reflective single element or alloy, for example, silver (Ag). In one embodiment, a silver (Ag) first contact 810 directly contacts the surface 803 of the first semiconductor layer 804, without an intervening layer of nickel (Ni), or any other material that reduces the reflectivity of the silver (Ag) first contact 810. A bonding layer 813 is deposited over the first contact 810 and the portions of the surface 803 of the first semiconductor layer 804 which are not covered by the first contact 810. When heat and pressure are applied, bonding layer 813 bonds the handling substrate 802 to the LED 801.

In one embodiment, the first contact 810 is annealed prior to eutectically bonding the handling substrate 802 to the LED 801. Annealing the first contact 810 creates an ohmic connection between the first contact 810 and the first semiconductor layer 804. In one embodiment, the first contact 810 is annealed at a temperature between about 300° C. and about 450° C. The first contact 810 is annealed in an environment comprising nitrogen (N₂) and oxygen (O₂). In one embodiment, the first contact 810 is annealed for less than two minutes. In another embodiment, the first contact 810 is preferably annealed for about one minute.

As previously discussed, the oxidized region 814 of the first layer 804 suppresses agglomeration of the first contact 810 during the annealing process, resulting in a first contact 810 having a substantially planar surface and a substantially uniform thickness. The first contact 810 is also substantially free from projections and indentations, such as the Ag islands shown in FIG. 5. As a result, the first contact 810 has an optical reflectivity after the annealing step substantially similar to an optical reflectivity of the first contact 810 after deposition, but before annealing. In other words, annealing does not noticeably degrade the reflectivity of the first contact 810. In one embodiment, the first contact 810 has an optical reflectivity between about 90% and about 99%. In one embodiment, the first contact 810 has an optical reflectivity greater than 94%, and up to 99%.

In FIG. 8F, the growth substrate 800 is removed using any known method. In one embodiment, the growth substrate 800 is removed using chemical etching. In another embodiment, the growth substrate 800 is removed using Laser Lift Off (LLO). In yet another embodiment, the growth substrate 800 is removed using mechanical grinding. In yet another embodiment, the growth substrate 800 is removed using dry etching, such as inductively coupled plasma reactive ion etching (RIE). In FIG. 8G, the first semiconductor layer 804, the light emitting layer 806, and the second semiconductor layer 808 of the LED 801 are etched to form a mesa structure to facilitate dicing of the LED 801 to create individual LED assemblies. A second contact 812 is formed on the second semiconductor layer 808, and is electrically coupled to the second semiconductor layer. The LED assembly shown in FIG. 8G is a completed vertical LED assembly according to one embodiment of the invention.

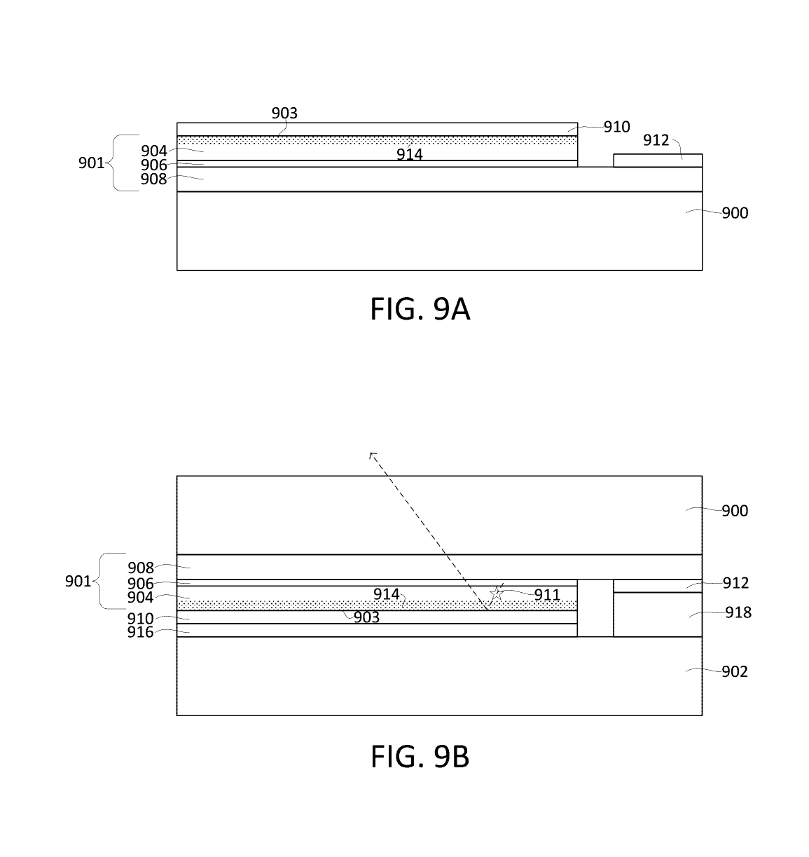

FIGS. 9A and 9B show cross-sectional views of alternative manufacturing steps to form a flip-chip LED assembly according to another embodiment of the invention. Prior to the step shown in FIG. 9A, the previous manufacturing steps are substantially the same as the manufacturing steps shown in FIGS. 8A-8E. In FIG. 9A, instead of bonding a handling substrate as shown in FIG. 8E, a portion of the first semiconductor layer 904 and the light emitting layer 906 is etched to expose a portion of the second semiconductor layer 908. A first contact 910 is deposited on the surface 903 of the first semiconductor layer 904, and a second contact 912 is deposited on the exposed portion of the second semiconductor layer 908. As in FIG. 8E, the first contact 910 comprises a highly reflective single element or alloy, for example, silver (Ag). In one embodiment, a silver (Ag) first contact 910 directly contacts the surface 903 of the first semiconductor layer 904, without an intervening layer of nickel (Ni), or any other material that reduces the reflectivity of the silver (Ag) first contact 910. The second contact 912 may comprise any material suitable to form an ohmic contact with the second semiconductor layer 908, such as titanium (Ti), gold (Au), silver (Ag), or aluminum (Al). It is not necessary for the second contact 912 to be highly reflective, as the light emitting layer 906 was etched away to allow for the second contact 912 to contact the second layer 908.

Both the first and the second contacts 910 and 912 are annealed to form an ohmic contact with the first semiconductor layer 904, and the second semiconductor layer 908, respectively. In one embodiment, the annealing occurs at a temperature greater than 300° C. and 450° C. The annealing environment comprises nitrogen (N₂) and oxygen (O₂). In one embodiment, the first contact 910 and the second contact 912 are annealed for less than two minutes. In another embodiment, the first contact 910 and the second contact 912 are preferably annealed for about one minute. Again, the oxidized region 914 of the first layer 904 suppresses agglomeration of the first contact 910 during the annealing process. As a result, the first contact 910 has an optical reflectivity after the annealing step substantially similar to an optical reflectivity of the first contact 910 after deposition, but before annealing.

In FIG. 9B, a submount having a first interconnect 916 and a second interconnect 918 is attached to the LED 901, with the first contact 910 electrically coupled to the first interconnect 918, and the second contact 912 electrically coupled to the second interconnect 918. The LED assembly shown in FIG. 9B is a completed flip-chip LED assembly according to one embodiment of the invention. Optionally, if a non-transparent growth substrate 900 was used, the growth substrate may be removed to allow photons 911 emitted by the light emitting layer 906 to escape during device operation.

In either embodiment, whether a flip-chip or vertical LED assembly structure is used, the LED assemblies manufactured using the steps shown in FIGS. 8A-8G and FIGS. 9A-9B will have improved light output power over prior art LED assemblies because the oxidized regions 814 and 914 suppresses agglomeration of the first contacts 810 and 910 during annealing, respectively, and as such, eliminates the need for optically degrading materials, such as nickel (Ni) or titanium oxide (TiO₂). As such, the reflectivity of the first contacts 810 and 910 after annealing will be substantially similar to the reflectivity of the first contacts 810 and 910 after its deposition and before annealing, respectively. The observed improvement in light output power will scale linearly with the increase in operating conditions, making the LED assembly formed by the manufacturing steps shown in FIGS. 8A-8G and 9A-9B suitable for both low-power and high-power applications.

Referring back to the step shown in FIG. 8E, additional surface treatments to form the oxidized region 814, aside from oxygen (O₂) plasma ashing, were also considered. The other surface treatments include, oxygen (O₂) reactive-ion etching (O₂-RIE), application of hydrofluoric acid (1:10 ratio of HF to H₂O), buffered oxide etching (BOE; 1:4:5 ratio HF to NH₄F to H₂O), application of nitric acid (1:1 ratio HNO₃ to H₂O), application of hydrochloric acid (1:1 ratio HCl to H₂O), application of phosphoric acid (H₃PO₄), and application of piranha solution (5:1 ratio of H₂SO₄ to H₂O₂). To evaluate the effectiveness of the various surface treatments, the reflectivity of a 100 nm silver (Ag) layer deposited on the surface 803 of the first semiconductor layer 804 was measured before and after annealing for each treatment:

TABLE 8-1a

| Treatment | O₂ Asher | O₂-RIE | HF:H₂O | BOE |
|---|---|---|---|---|
| Ag reflectivity | 96.43% | 93.84% | 95.55% | 95.79% |
| before anneal | | | | |
| Ag reflectivity after | 95.08% | 65.99% | 81.59% | 83.27% |
| anneal | | | | |
| Efficiency | 98.60% | 70.32% | 85.39% | 86.93% |

TABLE 8-1b

| Treatment | HNO₃:H₂O | HCl:H₂O | H₃PO₄ | H₂SO₄:H₂O₂ |
|---|---|---|---|---|
| Ag reflectivity | 96.31% | 95.76% | 97.25% | 94.54% |
| before anneal | | | | |
| Ag reflectivity after | 93.95% | 91.29% | 86.92% | 91.00% |
| anneal | | | | |
| Efficiency | 97.55% | 95.33% | 89.38% | 96.26% |

In Tables 8-1a and 8-1b, it can be seen that oxygen (O₂) plasma ashing resulted in the highest efficiency (reflectivity % before anneal/reflectivity % after anneal) out of all the other surface treatments tested, and the only surface treatment to result in a reflectivity of the silver (Ag) above 94% after annealing. Additionally, oxygen (O₂) plasma ashing resulted in the smoothest surface of the silver (Ag) layer after annealing, with very little to no perceptible agglomeration under dark field imaging. Every other surface treatment showed slight to severe agglomeration of the silver (Ag) layer under dark field imaging. While slight agglomeration of the silver (Ag) layer was observed for the nitric acid (HNO₃:H₂O), hydrochloric acid (HCl:H₂O), and piranha solution (H₂SO₄ to H₂O₂) treatments, it is understood that these treatments are also effective to achieve a greater than 90% reflectivity of the silver (Ag) layer, and are suitable for forming the oxidized region 814 according to other embodiments of the invention.

Other objects, advantages and embodiments of the various aspects of the present invention will be apparent to those who are skilled in the field of the invention and are within the scope of the description and the accompanying Figures. For example, but without limitation, structural or functional elements might be rearranged, or method steps reordered, consistent with the present invention. Similarly, principles according to the present invention could be applied to other examples, which, even if not specifically described here in detail, would nevertheless be within the scope of the present invention.

What is claimed is:

1. A light emitting diode (LED) assembly comprising:
an LED comprising a light emitting layer disposed between a first layer comprising a group III-V semiconductor material having a first conductivity type and a second layer comprising the group III-V semiconductor material having a second conductivity type, the first layer having an oxidized region extending inwards of a surface of the first layer opposite the second layer; and
a first contact disposed on the surface of the first layer opposite the second layer and electrically coupled to the first layer.

2. The LED assembly of claim 1, further comprising a second contact disposed on a surface of the second layer and electrically coupled to the second layer.

3. The LED assembly of claim 1, wherein the oxidized region has a ratio of a concentration of oxygen to a concentration of the group III element of 1:1000 to 1:10.

4. The LED assembly of claim 1, wherein the oxidized region extends up to 70 nm inwards of the surface of the first layer opposite the second layer.

5. The LED assembly of claim 1, wherein the group III-V semiconductor material is gallium nitride (GaN).

6. The LED assembly of claim 5, wherein the oxidized region comprises gallium oxide (Ga₂O₃).

7. The LED assembly of claim 1, wherein the first contact comprises a single element or alloy.

8. The LED assembly of claim 1, wherein the first contact is silver (Ag)

9. The LED assembly of claim 1, wherein the first contact is substantially free of nickel (Ni), zinc (Zn), palladium (Pd), titanium (Ti), or any material having an optical reflectivity lower than silver (Ag) at the interface of the first contact and the first layer.

10. The LED assembly of claim 1, wherein the first contact forms an ohmic contact with the first layer.

11. The LED assembly of claim 1, wherein the first contact has a substantially uniform thickness.

12. The LED assembly of claim 1, wherein a surface of the first contact opposite the first layer is substantially planar.

13. The LED assembly of claim 1, wherein a surface of the first contact opposite the first layer is substantially free of projections and indentations.

14. The LED assembly of claim 1, wherein the first contact has an optical reflectivity between 90% to 99%.

15. A method of forming a light emitting diode (LED) assembly comprising:
providing a substrate;
forming an LED on a surface of the substrate, the LED comprising a light emitting layer disposed between a first layer comprising a group III-V semiconductor material having a first conductivity type and a second layer comprising the group III-V semiconductor material having a second conductivity type;
forming an oxidized region extending inwards of a surface of the first layer opposite the second layer; and
depositing a first contact on the surface of the first layer.

16. The method of claim 15, further comprising:
depositing a second contact on the second layer.

17. The method of claim 15, wherein the oxidized region has a ratio of a concentration of oxygen to a concentration of the group III element of 1:1000 to 1:10.

18. The method of claim 15, wherein the oxidized region extends up to 70 nm inwards of the surface of the first layer opposite the second layer.

19. The method of claim 15, further comprising:
baking the LED before the step forming the oxidized region.

20. The method of claim 19, wherein the LED is baked in an environment comprising nitrogen (N₂) and oxygen (O₂).

21. The method of claim 19, wherein the LED is baked for less than 10 minutes.

22. The method of claim 15, wherein the oxidized region is formed by oxygen (O₂) plasma ashing the surface of the first layer.

23. The method of claim 15, wherein the group III-V semiconductor material is gallium nitride (GaN).

24. The method of claim 23, wherein the oxidized region comprises gallium oxide (Ga₂O₃).

25. The method of claim 15, further comprising:
annealing the first contact, forming an ohmic contact between the first contact and the first layer.

26. The method of claim 25, wherein the first contact is annealed at a temperature between about 300° C. to about 450° C.

27. The method of claim 25, wherein the first contact is annealed in an environment comprising nitrogen (N₂) and oxygen (O₂).

28. The method of claim 25, wherein the first contact is annealed for less than 2 minutes.

29. The method of claim 25, wherein the first contact has a substantially uniform thickness after the annealing step.

30. The method of claim 25, wherein a surface of the first contact opposite the first layer is substantially planar after the annealing step.

31. The method of claim 25, wherein a surface of the first contact opposite the first layer is substantially free of projections and indentations after the annealing step.

32. The method of claim 25, wherein the first contact has an optical reflectivity after the annealing step substantially similar to an optical reflectivity of the first contact after the deposition step and before the annealing step.

33. The method of claim 25, wherein the first contact has an optical reflectivity between 90% to 99%.

34. The method of claim 15, wherein the first contact comprises a single element or alloy.

35. The method of claim 15, wherein the first contact is silver (Ag).

36. The method of claim 15, wherein the first contact is substantially free of nickel (Ni), zinc (Zn), palladium (Pd), titanium (Ti), or any material having an optical reflectivity lower than silver (Ag), at the interface of the first contact and the first layer.
